(19) United States
(12) Patent Application Publication
(10) Pub. No.: US 2022/0406751 A1
(43) Pub. Date: Dec. 22, 2022

(54) QUASI-MONOLITHIC HIERARCHICAL INTEGRATION ARCHITECTURE

(71) Applicant: Intel Corporation, Santa Clara, CA (US)

(72) Inventors: Adel A. Elsherbini, Tempe, AZ (US); Shawna M. Liff, Scottsdale, AZ (US); Johanna M. Swan, Scottsdale, AZ (US); Julien Sebot, Portland, OR (US)

(73) Assignee: Intel Corporation, Santa Clara, CA (US)

(21) Appl. No.: 17/354,773

(22) Filed: Jun. 22, 2021

(51) Int. Cl. H01L 25/065; H01L 23/00; H01L 21/683

(52) U.S. Cl. CPC H01L 25/0652; H01L 24/24; H01L 24/19; H01L 24/27; H01L 24/83; H01L 24/32; H01L 24/16; H01L 21/6835; H01L 24/73; H01L 2224/24147; H01L 2224/24226; H01L 2224/32145; H01L 2224/32225; H01L 2224/16225; H01L 2224/82005; H01L 2224/73209; H01L 2224/73217; H01L 2224/73253; H01L 2924/37001

(57) ABSTRACT

A microelectronic assembly is provided, comprising: a first integrated circuit (IC) die at a first level, a second IC die at a second level, and a third IC die at a third level, the second level being in between the first level and the third level. A first interface between the first level and the second level is electrically coupled with high-density interconnects of a first pitch and a second interface between the second level and the third level is electrically coupled with interconnects of a second pitch. In some embodiments, at least one of the first IC die, second IC die, and third IC die comprises another microelectronic assembly. In other embodiments, at least one of the first IC die, second IC die, and third IC die comprises a semiconductor die.

### TECHNICAL FIELD

The present disclosure relates to techniques, methods, and apparatus directed to quasi-monolithic hierarchical integration architecture in semiconductor integrated circuit (IC) packaging.

### BACKGROUND

Electronic circuits when commonly fabricated on a wafer of semiconductor material, such as silicon, are called ICs. The wafer with such ICs is typically cut into numerous individual dies. The dies may be packaged into an IC package containing one or more dies along with other electronic components such as resistors, capacitors, and inductors. The IC package may be integrated onto an electronic system, such as a consumer electronic system.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a schematic block diagram of an example microelectronic assembly architecture, according to some embodiments of the present disclosure.

FIG. 1B is a schematic cross-sectional view of a portion of the example microelectronic assembly of FIG. 1A.

FIG. 2 is a schematic cross-sectional view of an example IC packaging architecture comprising a microelectronic assembly, according to some embodiments of the present disclosure.

FIG. 3 is a schematic cross-sectional view of another example IC packaging architecture, according to some embodiments of the present disclosure.

FIGS. 4A-4C are schematic block diagrams of yet another example IC packaging architecture, according to some embodiments of the present disclosure.

FIG. 5 is a schematic cross-sectional view of yet another example IC packaging architecture, according to some embodiments of the present disclosure.

FIG. 6 is a schematic cross-sectional view of yet another example IC packaging architecture, according to some embodiments of the present disclosure.

FIGS. 7A-7J are schematic cross-sectional views of different stages of manufacture of a microelectronic assembly, according to some embodiments of the present disclosure.

FIG. 8 is a flow diagram of an example method of fabricating a microelectronic assembly, according to various embodiments of the present disclosure.

FIG. 9 is a cross-sectional view of a device package that includes one or more microelectronic assemblies in accordance with any of the embodiments disclosed herein.

FIG. 10 is a cross-sectional side view of a device assembly that includes one or more microelectronic assemblies in accordance with any of the embodiments disclosed herein.

FIG. 11 is a block diagram of an example computing device that includes one or more microelectronic assemblies in accordance with any of the embodiments disclosed herein.

### DETAILED DESCRIPTION

Overview

For purposes of illustrating IC packages described herein, it is important to understand phenomena that may come into play during assembly and packaging of ICs. The following foundational information may be viewed as a basis from which the present disclosure may be properly explained. Such information is offered for purposes of explanation only and, accordingly, should not be construed in any way to limit the broad scope of the present disclosure and its potential applications.

Advances in semiconductor processing and logic design have permitted an increase in the amount of logic circuits that may be included in processors and other IC devices. As a result, many processors now have multiple cores that are monolithically integrated on a single die. Generally, these types of monolithic ICs are also described as planar since they take the form of a flat surface and are typically built on a single silicon wafer made from a monocrystalline silicon boule. The typical manufacturing process for such monolithic ICs is called a planar process, allowing photolithography, etching, heat diffusion, oxidation, and other such processes to occur on the surface of the wafer, such that active circuit elements (e.g., transistors and diodes) are formed on the planar surface of the silicon wafer.

Current technologies permit hundreds and thousands of such active circuit elements to be formed on a single die so that numerous logic circuits may be enabled thereon. In such monolithic dies, the manufacturing process must be optimized for all the circuits equally, resulting in trade-offs between different circuits. In addition, because of the limitation of having to place circuits on a planar surface, some circuits are farther apart from some others, resulting in decreased performance such as longer delays. The manufacturing yield may also be severely impacted because the entire die may have to be discarded if even one circuit is malfunctional.

One solution to overcome such negative impacts of monolithic dies is to disaggregate the circuits into smaller dies (e.g., chiplets. tiles) electrically coupled by interconnect bridges. The smaller dies are part of an assembly of interconnected dies that together form a complete IC in terms of application and/or functionality, such as a memory chip, microprocessor, microcontroller, commodity IC (e.g., chip used for repetitive processing routines, simple tasks, application specific IC, etc.), and system-on-a-chip (SoC). In other words, the individual dies are connected together to create the functionalities of a monolithic IC. By using separate dies, each individual die can be designed and manufactured optimally for a particular functionality. For example, a processor core that contains logic circuits might aim for performance, and thus might require a very speed-optimized layout. This has different manufacturing requirements compared to a USB controller, which is built to meet certain USB standards, rather than for processing speed. Thus, by having different parts of the overall design separated into different dies, each one optimized in terms of design and manufacturing, the overall yield and cost of the combined die solution may be improved.

The connectivity between these dies is achievable by many different ways. For example, in 2.5D packaging solutions, a silicon interposer and through-silicon vias (TSVs) connect dies at silicon interconnect speed in a minimal footprint. In another example, called Embedded Multi-Die Interconnect Bridge (EMIB), a silicon bridge embedded under the edges of two interconnecting dies facilitates electrical coupling between them. In a three-dimensional (3D) architecture, the dies are stacked one above the other, creating a smaller footprint overall. Typically, the electrical connectivity and mechanical coupling in such 3D architecture is achieved using TSVs and high pitch solder-based bumps (e.g., C2 interconnections). The EMIB and the 3D stacked architecture may also be combined using an omni-directional interconnect (ODI), which allows for top-packaged chips to communicate with other chips horizontally using EMIB and vertically, using Through-Mold Vias (TMVs) which are typically larger than TSVs. However, these current interconnect technologies use solder or its equivalent for connectivity, with consequent low vertical and horizontal interconnect density.

One way to mitigate low vertical interconnect density is to use an interposer, which improves vertical interconnect density but suffers from low lateral interconnect density if the base wafer of the interposer is passive. In a general sense, an “interposer” is commonly used to refer to a base piece of silicon that interconnects two dies. By including active circuitry in the interposer, lateral speeds may be improved, but it requires more expensive manufacturing processes, in particular when a large base die is used to interconnect smaller dies. Additionally, not all interfaces require fine pitch connections which may lead to additional manufacturing and processing overheads without the benefits of the fine pitch.

In one aspect of the present disclosure, an example of quasi-monolithic hierarchical integration of semiconductor dies includes recursively coupling a plurality of dies to form microelectronic assemblies of a processing system. The plurality of dies may comprise active dies and/or passive dies, and at least a portion of the plurality of dies are coupled using high-density interconnects. As used herein, “high-density interconnects” comprise die-to-die (DTD) interconnects with sub-10 micrometer pitch. In other words, the center-to-center separation between adjacent high-density interconnects is less than or equal to 10 micrometer. In one example embodiment, high-density interconnects may comprise hybrid direct interconnects.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices. The term “circuit” means one or more passive and/or active components that are arranged to cooperate with one another to provide a desired function. The term “interconnect” may be used to describe any element formed of an electrically conductive material for providing electrical connectivity to one or more components associated with an IC or/and between various such components. In general, the term “interconnect” may refer to both conductive lines (or, simply “lines,” also sometimes referred to as “traces” or “trenches”) and conductive vias (or, simply “vias”). In general, in context of interconnects, the term “conductive line” may be used to describe an electrically conductive element isolated by an insulator material (e.g., a low-k dielectric material) that is provided within the plane of an IC die. Such lines are typically stacked into several levels, or several layers, of a metallization stack. On the other hand, the term “via” may be used to describe an electrically conductive element that interconnects two or more lines of different levels. To that end, a via may be provided substantially perpendicularly to the plane of an IC die and may interconnect two lines in adjacent levels or two lines in not adjacent levels. The term “metallization stack” may be used to refer to a stack of one or more interconnects for providing connectivity to different circuit components of an IC chip. Sometimes, lines and vias may be referred to as “metal traces” and “metal vias”, respectively, to highlight the fact that these elements include electrically conductive materials such as metals.

Interconnects as described herein, in particular interconnects of the IC structures as described herein, may be used for providing electrical connectivity to one or more components associated with an IC or/and between various such components, where, in various embodiments, components associated with an IC may include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer. In another example, the terms “package” and “IC package” are synonymous, as are the terms “die” and “IC die,” the term “insulating” means “electrically insulating,” the term “conducting” means “electrically conducting,” unless otherwise specified.

In yet another example, if used, the terms “oxide,” “carbide,” “nitride,” etc. refer to compounds containing, respectively, oxygen, carbon, nitrogen, etc., the term “high-k dielectric” refers to a material having a higher dielectric constant than silicon oxide, while the term “low-k dielectric” refers to a material having a lower dielectric constant than silicon oxide.

The terms “substantially,” “close,” “approximately,” “near,” and “about,” generally refer to being within +/−20% of a target value (e.g., within +/−5 or 10% of a target value) based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers. In addition, the term “dispose” as used herein refers to position, location, placement, and/or arrangement rather than to any particular method of formation.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. When used herein, the notation “A/B/C” means (A), (B), and/or (C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated. Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

In the drawings, a particular number and arrangement of structures and components are presented for illustrative purposes and any desired number or arrangement of such structures and components may be present in various embodiments. Further, the structures shown in the figures may take any suitable form or shape according to material properties, fabrication processes, and operating conditions.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

### Example Embodiments

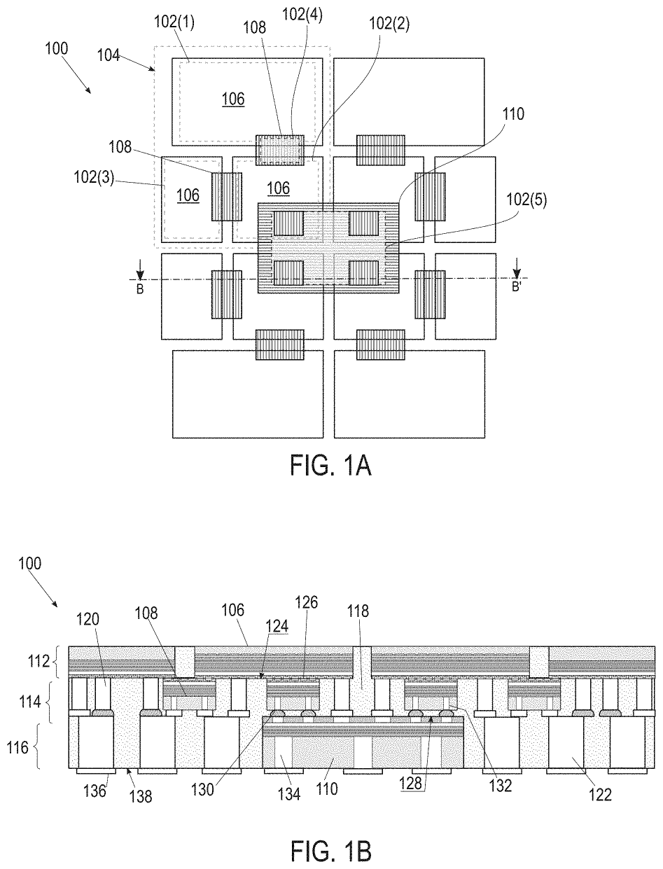

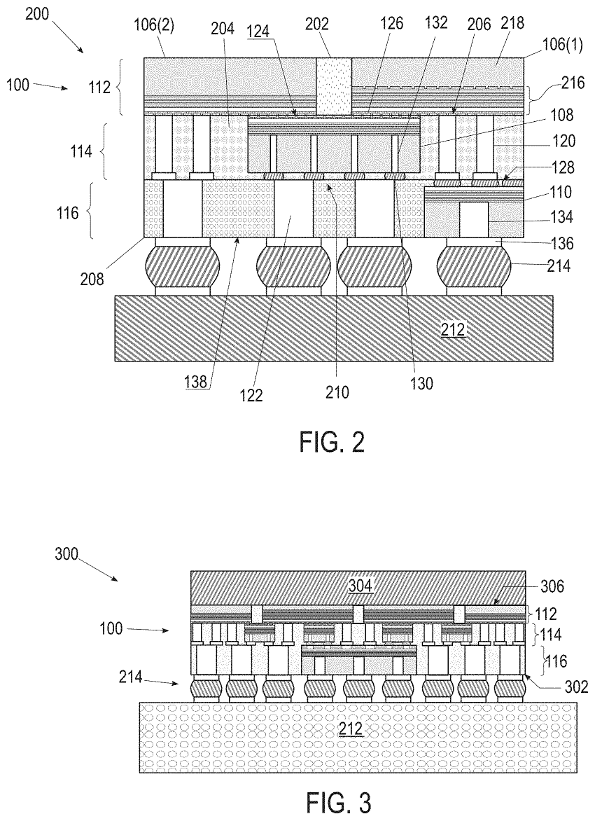

FIG. 1A is a schematic top view and block diagram of a microelectronic assembly 100 according to some embodiments of the present disclosure. Microelectronic assembly 100 comprises a plurality of circuit blocks 102. As used herein, the term “circuit block” refers to an intellectual property (IP) block (also called IP core) comprising an abstract circuit (e.g., virtual circuit as opposed to a physical circuit) of a reusable unit of logic, cell, or IC layout design with a particular functionality. For example, circuit block 102(1) may comprise a set of memory registers; circuit block 102(2) may comprise an arithmetic logic unit (ALU); circuit block 102(3) may comprise a power converter; circuit block 102(4) may comprise a local interconnect block; and circuit block 102(5) may comprise a global interconnect block. A portion of the plurality of circuit blocks 102 may function together as a processing element (PE) 104 in some embodiments. PE 104 may comprise, for example, a combination of memory block 102(1), ALU 102(2) and power converter 102(3), along with local interconnect blocks 102(4) and global interconnect block 102(5). PE 104, like circuit block 102, is a conceptual circuit (e.g., abstract circuit) as opposed to a physical one.

Embodiments of the present disclosure may facilitate composite PEs 104, which can be combined together to form a larger computing structure, which in turn may be further combined to form a larger number of cores. Local interconnect blocks 102(4) may represent electrical coupling between circuit blocks in the same PE 104, such as between memory block 102(1) and ALU 102(2), or between power converter 102(2) and ALU 102(2), or between different portions of ALU 102(2). Global interconnect block 102(5) may represent electrical coupling between circuit block 102 in different PE 104.

The physical embodiment of circuit block 102 and PE 104 comprises IC dies 106, 108 and 110 of microelectronic assembly 100 located on at least three levels respectively: a first level 112, a second level 114, and a third level 116, in which second level 114 is in between first level 112 and third level 116. In some embodiments, one or more IC dies 106, 108 and 110 may comprise ultra-small semiconductor dies with footprint less than 10 mm². In some other embodiments, one or more IC dies 106, 108 and 110 may comprise semiconductor dies of any size. In yet other embodiments, one or more IC dies 106, 108 and 110 may comprise other microelectronic assemblies, such as microelectronic assembly 100, in a recursive (e.g., nested, hierarchical) arrangement. For example, IC die 108 may comprise structures and components substantially similar to microelectronic assembly 100. In yet other embodiments, one or more IC dies 106, 108 and 110 may comprise a plurality of semiconductor dies stacked one on top of another, electrically coupled with high-density interconnects.

In some embodiments (e.g., as shown), PE 104 may be embodied as a portion of microelectronic assembly 100. In other embodiments, each PE 104 may be embodied in a separate microelectronic assembly 100. In the example embodiment shown, circuit blocks 102(1), 102(2) and 102(3) may be embodied in separate dies comprising first-level IC die 106 located at first level 112; circuit block 102(4) may be embodied in a die comprising second-level IC die 108 located at second level 114; and circuit block 102(5) may be embodied in a die comprising third-level IC die 110 located at third level 116.

Any suitable combination, layout, configuration, or arrangement of various circuit blocks 102 and PE 104 and corresponding IC dies 106, 108, and 110 may be used within the broad scope of the embodiments of the present disclosure. For example, multiple such microelectronic assemblies may be stacked within a single package. Microelectronic assembly 100 may comprise an IC, such as a microprocessor, in some embodiments. In other embodiments, microelectronic assembly 100 may form a portion (e.g., system controller block) of a larger IC, such as a microprocessor, a central processing unit (CPU), a memory device, e.g., a high-bandwidth memory device, a logic circuit, input/output circuitry, a transceiver such as a field programmable gate array transceiver, a gate array logic such as a field programmable gate array logic, of a power delivery circuitry, a III-V or a III-N device such as a III-N or III-N amplifier (e.g., GaN amplifier), Peripheral Component Interconnect Express circuitry, Double Data Rate transfer circuitry, or other electronic components known in the art.

FIG. 1B is a schematic cross-section of microelectronic assembly 100 across section BB′ that illustrates the three levels and embedded components more clearly. IC dies 106, 108 and 110 may be disposed in an insulator 118. Through-connections 120 (e.g., TMVs) may be disposed in insulator 118 at second level 114. Through-connections 122 (e.g., TMVs) may be disposed in insulator 118 at third level 116. Through-connections 120 and 122 may facilitate power delivery and high-speed signaling to first-level IC die 106. Interface 124 between first level 112 and second level 114 may be electrically coupled with DTD interconnects, for example, interconnects 126. In some embodiments, interconnects 126 may comprise hybrid bond interconnects. As used herein, the term “interface” refers to a boundary, a joint, or attached surfaces of dissimilar materials. Interface 128 between second level 114 and third level 116 may be electrically coupled with DTD interconnects 130. In some embodiments, the pitch of DTD interconnects 130 may be smaller than the pitch of DTD interconnects 126. In various embodiments, DTD interconnects 130 may comprise hybrid bond interconnects, micro-bumps, copper pillar interconnects, or flip-chip interconnects. Second-level IC die 108 may comprise TSVs 132 and third-level IC die 110 may comprise TSVs 134 in some embodiments. In other embodiments, TSVs may be absent in one or both of second-level IC die 108 and third-level IC die 110. Bond pads 136 at a bottom surface 138 of third level 116 may facilitate electrically coupling microelectronic assembly 100 to other components, such as a package substrate, or to other microelectronic assemblies.

Note that FIGS. 1A-1B are intended to show relative arrangements of the components within their assemblies, and that, in general, such assemblies may include other components that are not illustrated (e.g., various interfacial layers or various other components related to optical functionality, electrical connectivity, or thermal mitigation). For example, in some further embodiments, the assembly as shown in FIGS. 1A-1B may include multiple dies and/or XPUs along with other electrical components.

Additionally, although some components of the assemblies are illustrated in FIGS. 1A-1B as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

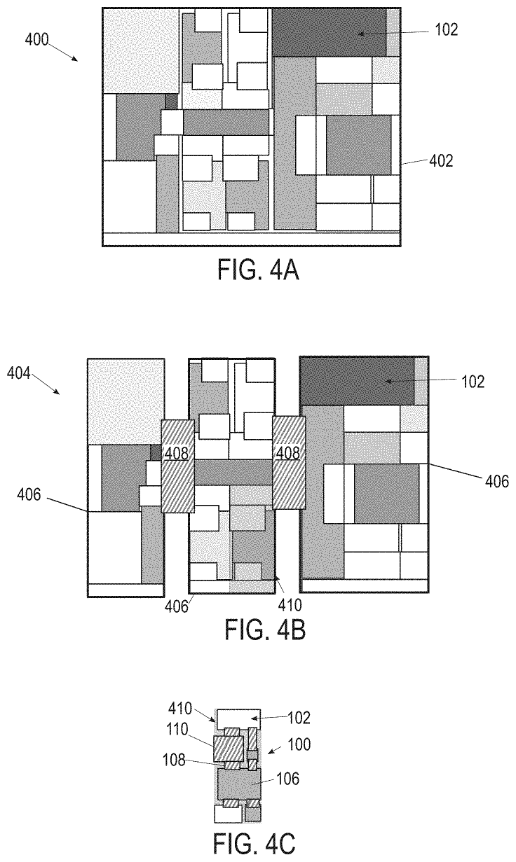

FIG. 2 is a schematic cross-sectional illustration of a microelectronic assembly 200, according to some embodiments of the present disclosure. Microelectronic assembly 200 comprises microelectronic assembly 100 having at least three levels: first level 112, second level 114, and third level 116. First level 112 comprises one or more first-level IC die 106, for example, 106(1) and 106(2) in the example shown, and an insulator 202. First-level IC die 106 may or may not include TSVs. Second level 114 comprises one or more second-level IC die 108 surrounded by an insulator 204, through which are disposed one or more conductive through-connections 120 (e.g., TMVs). Insulator 204 may comprise the same material as insulator 202 in some embodiments; in other embodiments, insulator 204 may comprise a different material. Second-level IC die 108 may include TSVs 132. Interface 124 between first level 112 and second level 114 may be electrically and mechanically coupled with high-density interconnects 126 having a minimum pitch 206. As used herein, the term “pitch” refers to a center-to-center distance between adjacent interconnects. In an example embodiment, pitch 206 may be approximately 2 micrometers (microns) or smaller. In other example embodiments, pitch 206 may be approximately 2 micrometers or larger.

Third level 116 may comprise one or more third-level IC die 110, which may comprise TSVs 134. Third-level IC die 110 may be surrounded by an insulator 208, in which through-connections 122 (e.g., TMVs) are disposed. Insulator 208 may comprise the same material as insulator 204 of first level 112 or insulator 204 of second level 114 in some embodiments; in other embodiments, insulator 204 may comprise a different material than either. Interface 128 between second level 114 and third level 116 may be electrically and mechanically coupled with interconnects 130 having a minimum pitch 210. In an example embodiment, pitch 210 may be 10 micrometer. In some embodiments, interconnects 130 may comprise high-density interconnects (e.g., hybrid bond interconnects); in other embodiments, interconnects 130 may comprise other forms of DTD interconnects (e.g., micro-bumps, copper pillar interconnects, or flip-chip interconnects). In various embodiments, third level 116 may be electrically and mechanically coupled to a package substrate 212 with interconnects 214.

In some embodiments, package substrate 212 may comprise a printed circuit board (PCB) comprising multiple layers of conductive traces embedded in organic dielectric. For example, package substrate 212 may comprise a laminate substrate with several layers of metal planes or traces that are interconnected to each other by through-hole plated vias, with input/output routing planes on the top and bottom layers, while the inner layers are used as a ground and power plane. In other embodiments, package substrate 212 may comprise an organic interposer; in yet other embodiments, package substrate may comprise an inorganic interposer (e.g., made of glass, ceramic or semiconductor materials). In yet other embodiments, package substrate 212 may comprise a composite of organic and inorganic materials, for example, with an embedded semiconductor die in an organic substrate. In some embodiments, interconnects 214 may comprise die-to-package-substrate (DTPS) interconnects; in other embodiments, for example, where package substrate 212 comprises a semiconductor interconnect bridge, interconnects 214 may comprise DTD interconnects.

In some embodiments, any of insulators 202, 204 and 208 may include a dielectric material, such as silicon dioxide, silicon carbon nitride, silicon nitride, oxynitride, polyimide materials, glass reinforced epoxy matrix materials, organic materials such as silica filled epoxy, or a low-k or ultra-low-k dielectric (e.g., carbon-doped dielectrics, fluorine-doped dielectrics, porous dielectrics, organic polymeric dielectrics, photo-imageable dielectrics, and/or benzocyclobutene-based polymers). In some embodiments any of insulators 202, 204 and 208 may include a semiconductor material, such as silicon, germanium, or a III-V material (e.g., gallium nitride), and one or more additional materials.

In an example embodiment one or more IC dies 106, 108 and 110 comprise a semiconductor die having a metallization stack 216 with a plurality of electrically conductive interconnects such as metal lines and vias extending through an insulator material fabricated using known semiconductor manufacturing processes. In some embodiments, one or more IC dies 106, 108 and 110 may comprise a semiconductor die with a substrate 218 including substantially monocrystalline semiconductors, such as silicon or germanium. In some other embodiments, the substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V, group II-VI, or group IV materials. In yet other embodiments, the substrate may comprise compound semiconductors, for example, with a first sub-lattice of at least one element from group III of the periodic table (e.g., Al, Ga, In), and a second sub-lattice of at least one element of group V of the periodic table (e.g., P, As, Sb). In yet other embodiments, the substrate may comprise an intrinsic IV or III-V semiconductor material or alloy, not intentionally doped with any electrically active impurity; in alternate embodiments, nominal impurity dopant levels may be present. In other embodiments, the substrate may comprise high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the substrate may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc.

Although not specifically shown in all of the present illustrations in order to not clutter the drawings, any interface (e.g., 124, 128) between two levels, a first level and a second level, described herein includes two surfaces: a first surface of the first level in contact with a second surface of the second level. When DTD or DTPS interconnects are described at the interface, the first surface may include a first set of conductive contacts, and the second surface may include a second set of conductive contacts. One or more conductive contacts of the first set may then be electrically and mechanically coupled to some of the conductive contacts of the second set by the DTD or DTPS interconnects.

The DTPS interconnects disclosed herein may take any suitable form. In various embodiments, DTPS interconnects may comprise interconnects 214 between third level 116 and package substrate 212. In some embodiments, a set of DTPS interconnects may include solder (e.g., solder bumps or balls that are subject to a thermal reflow to form the DTPS interconnects). DTPS interconnects that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of DTPS interconnects may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression.

The DTD interconnects disclosed herein may take any suitable form. In some embodiments, DTD interconnects may be high-density interconnects 126, comprising metal-to-metal interconnects (e.g., copper-to-copper interconnects, or plated interconnects). In such embodiments, the conductive contacts on either side of the DTD interconnect may be bonded together (e.g., under elevated pressure and/or temperature) without the use of intervening solder or an anisotropic conductive material. In some embodiments, a thin cap of solder may be used in a metal-to-metal interconnect to accommodate planarity, and this solder may become an intermetallic compound during processing. In some metal-to-metal interconnects that utilize hybrid bonding, a dielectric material (e.g., silicon oxide, silicon nitride, silicon carbide, or an organic layer) may be present between the metals bonded together (e.g., between copper pads or posts that provide the associated conductive contacts). In some embodiments, one side of a DTD interconnect may include a metal pillar (e.g., a copper pillar), and the other side of the DTD interconnect may include a metal contact (e.g., a copper contact) recessed in a dielectric. In some embodiments, a metal-to-metal interconnect (e.g., a copper-to-copper interconnect) may include a noble metal (e.g., gold) or a metal whose oxides are conductive (e.g., silver). In some embodiments, a metal-to-metal interconnect may include metal nanostructures (e.g., nanorods) that may have a reduced melting point. Metal-to-metal interconnects may be capable of reliably conducting a higher current than other types of interconnects; for example, some solder interconnects may form brittle intermetallic compounds when current flows, and the maximum current provided through such interconnects may be constrained to mitigate mechanical failure.

In some embodiments, the ICs on either side of a set of DTD interconnects may be unpackaged dies, and/or the DTD interconnects may include small conductive bumps or pillars (e.g., copper bumps or pillars) attached to the respective conductive contacts by solder. In some embodiments, some or all of the DTD interconnects (e.g., 130) may be solder interconnects that include a solder with a higher melting point than a solder included in some or all of the DTPS interconnects. For example, when the DTD interconnects are formed before the DTPS interconnects are formed, solder-based DTD interconnects may use a higher-temperature solder (e.g., with a melting point above 200 degrees Celsius), while the DTPS interconnects may use a lower-temperature solder (e.g., with a melting point below 200 degrees Celsius). In some embodiments, a higher-temperature solder may include tin; tin and gold; or tin, silver, and copper (e.g., 96.5% tin, 3% silver, and 0.5% copper). In some embodiments, a lower-temperature solder may include tin and bismuth (e.g., eutectic tin bismuth) or tin, silver, and bismuth. In some embodiments, a lower-temperature solder may include indium, indium and tin, or gallium.

In some embodiments, a set of DTD interconnects (e.g., 130) may include any appropriate solder material, such as any of the materials discussed above for the DTPS interconnects. In some embodiments, a set of DTD interconnects may include an anisotropic conductive material, such as any of the materials discussed above for the DTPS interconnects. In some embodiments, the DTD interconnects may be used as data transfer lanes, while the DTPS interconnects may be used for power and ground lines, among others.

In some embodiments, the pitch of the DTD interconnects may be different from the pitch of the DTPS interconnects, although, in other embodiments, these pitches may be substantially the same. In packages as described herein, some or all of the DTD interconnects may have a finer pitch than the DTPS interconnects. In some embodiments, the DTD interconnects may have too fine a pitch to couple to the package substrate directly (e.g., too fine to serve as DTPS interconnects). The DTD interconnects may have a smaller pitch than the DTPS interconnects due to the greater similarity of materials in the different dies on either side of a set of DTD interconnects than between a die and a package substrate on either side of a set of DTPS interconnects. In particular, the differences in the material composition of ICs and package substrates may result in differential expansion and contraction of the ICs and package substrates due to heat generated during operation (as well as the heat applied during various manufacturing operations). To mitigate damage caused by this differential expansion and contraction (e.g., cracking, solder bridging, etc.), the DTPS interconnects in any of the packages as described herein may be formed larger and farther apart than DTD interconnects, which may experience less thermal stress due to the greater material similarity of the pair of dies on either side of the DTD interconnects.

In some embodiments, the DTPS interconnects disclosed herein may have a pitch between about 80 micrometer and 300 micrometer, while the DTD interconnects disclosed herein may have a pitch between about 0.7 micrometer and 100 micrometer. In various embodiments, DTD interconnects may comprise high-density interconnects 126 between first level 112 and second level 114; DTD interconnects may also comprise interconnects 130 between second level 114 and third level 116. In various embodiments, minimum pitch 206 of high-density interconnects 126 or hybrid bond interconnects may be less than 10 micrometer. In some embodiments, minimum pitch 210 of interconnects 130 comprising micro-bumps (e.g., C2 bumps) may be between 10 micrometer and 50 micrometer; in other embodiments, minimum pitch 210 of interconnects 130 comprising fine pitch flip-chips (e.g., C4 bumps) may be between 20 micrometer and 100 micrometer.

In various embodiments, minimum pitch 206 at interface 124 between first level 112 and second level 114 may be less than or equal to 10 micrometer; minimum pitch 210 at interface 128 between second level 114 and third level 116 may be greater than 10 micrometer and less than 100 micrometer; the minimum pitch at the interface between third level 116 and package substrate 212 may be more than 80 micrometer, resulting in hierarchical pitches from finer pitches at first level 112 to increasingly coarser pitches at third level 116. Consequently, the pitch of through-connections 120 in second level 114 may be less than the pitch of through-connections 122 in third level 116. Likewise, the minimum pitch of TSVs 132 in second-level IC die 108 may be less than the minimum pitch of TSVs 134 in third-level IC die 110 in some embodiments.

This architecture encompassing hierarchical pitches allows dies of disparate manufacturing technologies (e.g., technology node, or process node, or simply node) to be coupled together seamlessly within microelectronic assembly 100. In a general sense, different nodes often imply different circuit generations and architectures. Smaller (or more recent) the technology node, smaller are the feature sizes, and consequently, the resulting transistors are both faster and more power-efficient. For example, microelectronic assembly 100 may include first-level IC die 106 manufactured using 10 nm process, second-level IC die 108 manufactured using 22 nm process and third-level IC die 110 manufactured using 45 nm process.

In various embodiments, IC dies 106, 108 and 110 may comprise ultra-small dies. In some embodiments, only first-level IC die 106 may comprise such ultra-small dies, while second-level IC die 106 and third-level IC die 110 may be of larger dimensions. In some embodiments, first-level IC die 106 may comprise single-side connections as depicted in the figure. In some embodiments, second-level IC die 108 may be passive and may facilitate electrical coupling between first-level IC die 106, for example, between first-level IC dies 106(1) and 106(2). In some embodiments, second-level IC die 108 may further comprise active circuit elements, for example, to provide additional networking functionalities. Likewise, third-level IC die 110 may be passive and may merely facilitate electrical coupling with second-level IC die 108, or with first-level IC die 106 in some embodiments. In other embodiments, third-level IC die 110 may comprise active circuit elements as well. Second-level IC die 108 and third-level IC die 110 may comprise double-side connections, for example, at two opposing interfaces between levels. In various embodiments, through-connections 120 in second level 114 and through-connections 122 in third level 116 may facilitate power delivery, high-speed signaling or across layer connections.

In various embodiments, selection of materials for insulators 202, 204 and 208 may be appropriately based on recursive re-implementation and hierarchical coupling of microelectronic assembly 100. Interconnects may also be hierarchically described: local within a single die, intermediate between dies in a microelectronic assembly, and global between hierarchical microelectronic assemblies. Such a quasi-monolithic hierarchical integration architecture allows process optimization for each individual circuit block 102. Where previously such circuit blocks 102 were incorporated into one large monolithic semiconductor die, embodiments of the present disclosure allow individual circuit blocks 102 to be implemented in individual dies using processing technology suitable for the functionality and/or design of circuit block 102, enabling much better yield and manufacturing improvements compared to global process node improvements. Embodiments of the present disclosure facilitate better reuse and configurability of CPUs and other processors and provide higher granularity/customizability in process selection and interconnect routing.

This architecture is particularly useful for multi-core architectures, where composite PEs 104 may be formed using two levels of dies which may then be combined together to form a larger computing structure. The larger computing structure may be further combined to form a larger number of cores. Some of PEs 104 may include non-Boolean logic dies with one or more of the neighboring dies serving as electrical/logical interconnect to the memory/external system. One particular flexibility in the structure may be the ability to vertically stack the different dies to improve functionality. For example, memory dies may be stacked one on top of another to increase capacity. In another example, ALUs implemented in individual dies may be stacked one on top of another for improved throughput if the thermal solution can handle the increased power densities of the stacked ALUs. The microelectronic assemblies as described herein may help to reduce the cost and improve line utilization if the interconnect density between the microelectronic assemblies may be satisfied with lower density interconnects. The arrangements as disclosed in the various embodiments described herein can also allow interoperability with devices from other manufacturers or other accelerators.

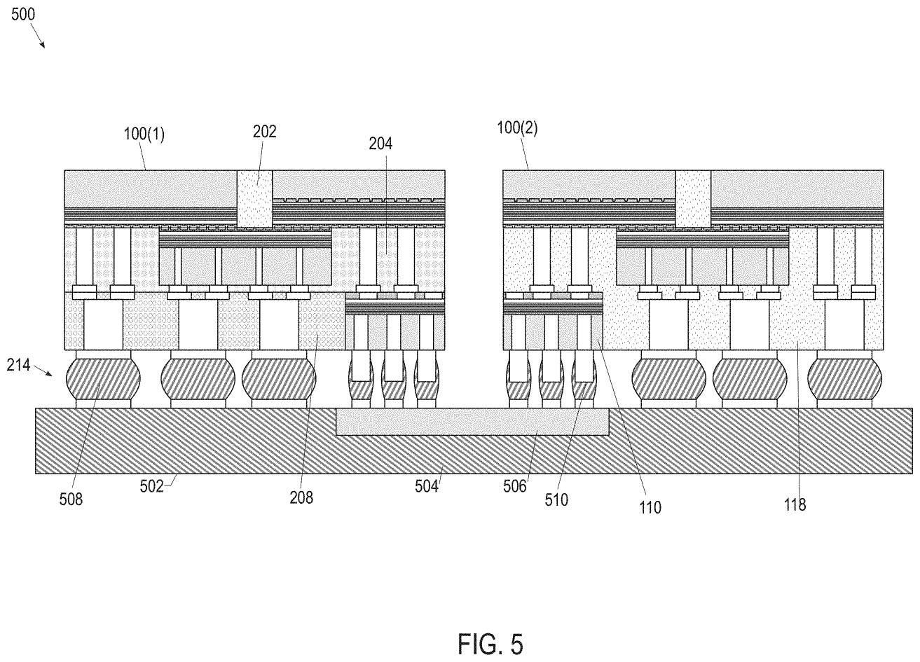

FIG. 3 is a simplified cross-sectional view of a microelectronic assembly 300 comprising microelectronic assembly 100 having three levels: first level 112, second level 114 and third level 116. Microelectronic assembly 100 may be coupled to package substrate 212 with DTPS interconnects 214 on surface 302. In some embodiments, microelectronic assembly 100 may be coupled to a stiffener 304 on a surface 306 opposite to surface 302. In some embodiments, stiffener 304 may comprise silicon; in other embodiments, stiffener 304 may comprise a ceramic material; in yet other embodiments, stiffener 304 may comprise a metal; in yet other embodiments, stiffener 304 may comprise a hard plastic. Any suitable material that can provide mechanical strength may be used. In some embodiments, stiffener 304 may also function as a heat sink.

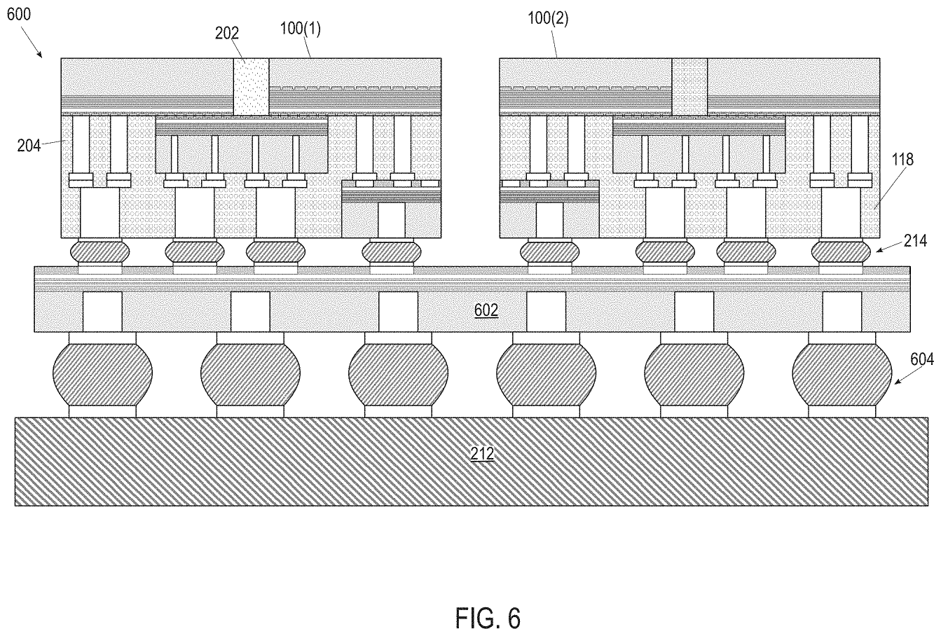

FIGS. 4A-4C are simplified top-views of different forms of an IC 400. FIG. 4A represents IC 400 embodied in a monolithic form 402. In monolithic form 402, all circuit blocks 102 that contribute to the functionality of IC 400 are embodied in a single wafer. FIG. 4B represents the same IC 400 embodied in a multi-chip module 404, wherein some circuit blocks 102 are embodied in separate dies 406 and interconnected using die bridges 408. FIG. 4C represents a portion 410 of multi-chip module 404, embodied as a microelectronic assembly 100 having IC dies 106, 108, and 110 at three levels according to embodiments of the present disclosure, each IC die comprising a separate circuit block 102. In various embodiments, one or more IC dies 106, 108, and 110 may be manufactured using one process node, and other IC dies 106, 108, and 110 may be manufactured using another process node.

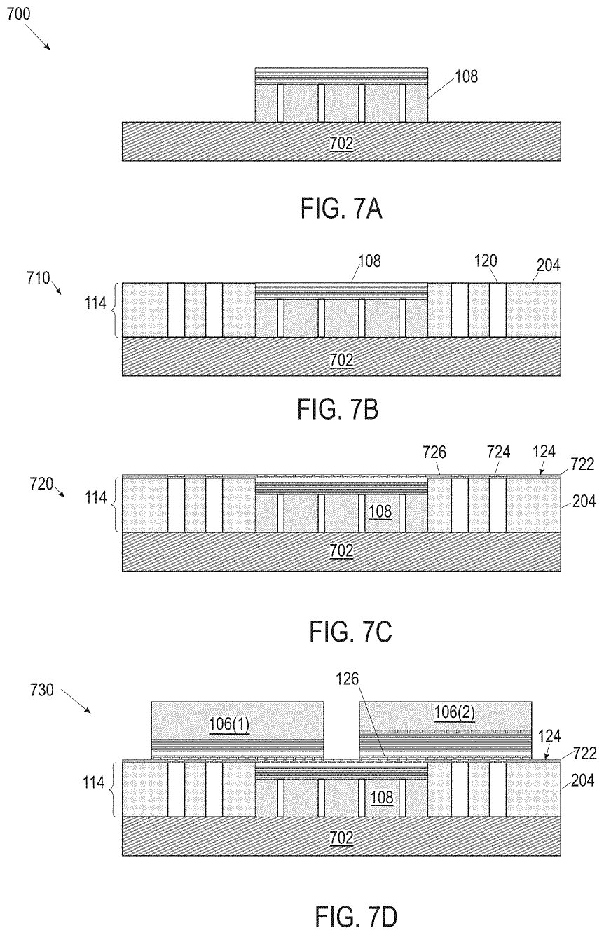

FIG. 5 is a simplified cross-sectional view of a microelectronics assembly 500 comprising a plurality of microelectronic assemblies 100 (e.g., 100(1) and 100(2)) coupled to an interposer 502 comprising an organic substrate 504 in which a bridge die 506 is embedded. In the embodiment shown for microelectronic assembly 100(1), insulators 202, 204 and 206 may comprise different materials at two or more different levels. In other embodiments, microelectronic assembly 100(2) may comprise insulator 118 being the same material in all three levels. Interconnects 214 coupling microelectronic assemblies 100 to interposer 506 may comprise DTD interconnects 508 and 510. Some DTD interconnects 508 coupling third level 116 with interposer 502 may be of a first pitch, and other DTD interconnects 510 located proximate to third-level IC die 110 may have a second pitch. For example, DTD interconnects 508 may comprise flip-chip interconnects with pitch around 80 micrometer, and DTD interconnects 510 may comprise micro-bumps with pitch around 30 micrometer.

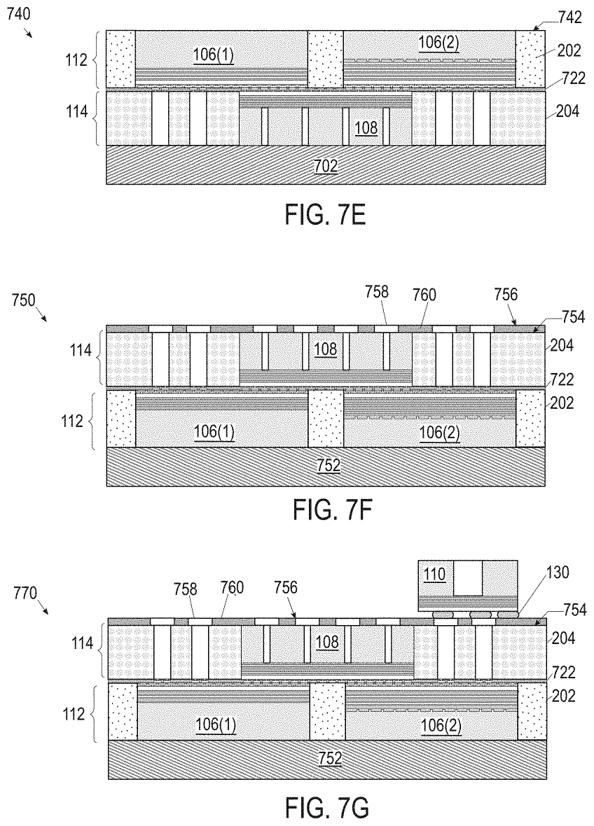

FIG. 6 is a simplified cross-sectional view of a microelectronics assembly 500 comprising a plurality of microelectronic assemblies 100 (e.g., 100(1) and 100(2)) coupled to a silicon interposer 602. In the embodiment shown for microelectronic assembly 100(1), insulators 202, 204 and 206 may comprise different materials at two or more different levels. In other embodiments, microelectronic assembly 100(2) may comprise insulator 118 being the same material in all three levels. Interconnects 214 coupling microelectronic assemblies 100 to silicon interposer 602 may comprise DTD interconnects of uniform pitch in the example shown. For example, interconnects 214 may comprise flip-chip interconnects with pitch around 80 micrometer. Silicon interposer 602, which may comprise active circuitry in some embodiments, may be coupled to package substrate 212 with DTPS interconnects 604.

In various embodiments, any of the features discussed with reference to any of FIGS. 1-6 herein may be combined with any other features to form a package with one or more ICs as described herein, for example, to form a modified IC package 100. Some such combinations are described above, but, in various embodiments, further combinations and modifications are possible.

### Example Methods

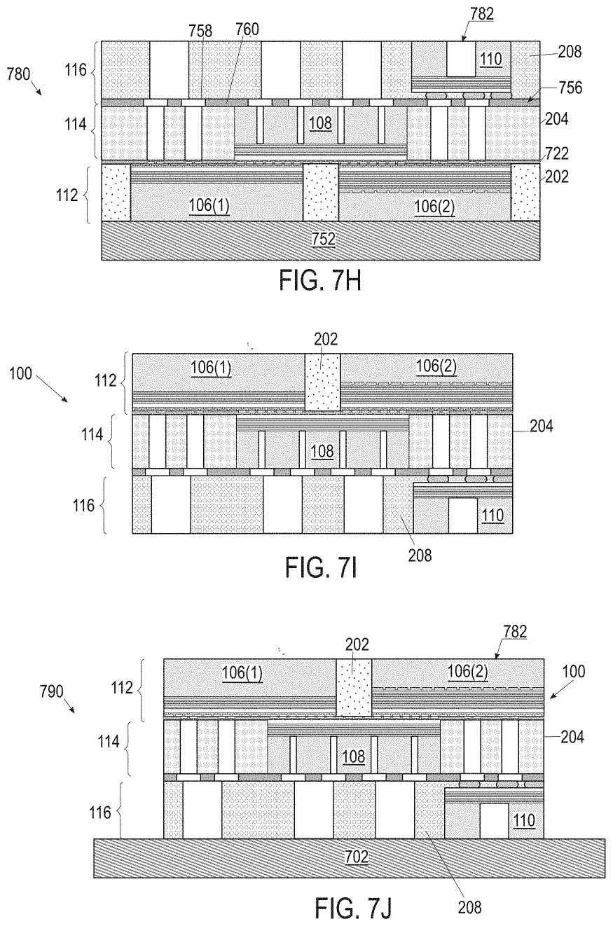

FIGS. 7A-7H show various stages of manufacture of microelectronic assembly 200 comprising microelectronic assembly 100. Assembly 700 comprises a carrier wafer 702, on which second-level IC die 108 may be attached suitably. Although only one second-level IC die 108 is shown, it is to be understood that a plurality of such IC dies may be attached to wafer 702 for wafer-level processing.

FIG. 7B shows assembly 710 subsequent to forming a reconstituted wafer. Insulator 204 is disposed around second-level IC die 108. In some embodiments, insulator 204 may comprise an organic material, such as mold compound. TMVs 120 may be formed in insulator 204 to complete second level 114.

FIG. 7C shows assembly 720 subsequent to forming a bonding layer 722, comprising bond pads 724 in an insulator 726. In some embodiments (e.g., as shown), bond pads 724 may correspond to high-density interconnects (e.g., 126). In other embodiments, bond pads 724 may correspond to solder-based pads, for example, flip-chips or micro-bumps. In yet other embodiments, bond pads 724 may correspond to pads (e.g., 136) for DTPS interconnects. In some embodiments, the material of insulator 726 may be the same as the material of insulator 204. For example, insulator 726 may comprise a polyimide, and insulator 204 may also comprise the polyimide. In other embodiments, the material of insulator 726 may be different from the material of insulator 204. For example, insulator 726 may comprise silicon oxide and insulator 204 may comprise mold compound.

FIG. 7D shows assembly 730 subsequent to attaching first-level IC die 106 to bonding layer 722. Any appropriate number of first-level IC die 106 may be attached to bonding layer 722 within the broad scope of the embodiments.

In the embodiment shown, first-level IC die 106 are attached with high-density interconnects 126. Assembly 730 may be subjected to appropriate processing to form high-density interconnects 126. For example, the bonding process may include applying a suitable pressure and heating assembly 730 to a suitable temperature (e.g., to moderately high temperatures, e.g., between about 50 and 200 degrees Celsius) for a duration of time. In some embodiments, a bonding material may be applied at interface 124 between first-level IC die 106 and bonding layer 722. The bonding material may be an adhesive that ensures attachment of first-level IC die 106 to bonding layer 722 in some embodiments. In other embodiments, the bonding material may be an etch-stop material. In yet other embodiments, the bonding material may be both an etch-stop material and have suitable adhesive properties to ensure attachment of first-level IC die 106 to bonding layer 722. In yet other embodiments, no bonding material may be used, in which case, the bonding interface may be recognizable as a seam or a thin layer in composite chipset 100, using, e.g., selective area diffraction (SED), even when the specific materials of the insulators of first-level IC die 106 and bonding layer 722 that are bonded together may be the same. In the latter case, the bonding interface may be noticeable as a seam or a thin layer in what otherwise appears as a bulk insulator (e.g., bulk oxide) layer.

In other embodiments, first-level IC die 106 may be attached with other DTD interconnects, in which case, the processing steps may vary accordingly. For example, solder reflow process may be employed to form solder-based bonds.

FIG. 7E shows assembly 740 subsequent to disposing insulator 202 over bonding layer 722 and around first-level IC die 106 to form first level 112. In some embodiments, the material of insulator 202 may be the same as for insulator 204. In other embodiments, the material of insulator 202 may be different from the material of insulator 204. Surface 742 of first level 112 may be planarized, for example, using grinding or chemical mechanical polishing (CMP).

FIG. 7F shows assembly 750 subsequent to further processing. Carrier wafer 702, which is disposed proximate to second level 114 opposite to first level 112, may be removed using known processes in the art. Another carrier wafer 752 may be attached to surface 742 of first level 112 and the assembly turned upside down so that carrier wafer 752 is on the bottom in a configuration wherein second level 114 is over first level 112, exposing surface 754 of second level 114. Bonding layer 756 may be formed on surface 754. Bonding layer 756 may comprise bond pads 758 in insulator 760. In some embodiments (e.g., as shown), bond pads 758 may correspond to solder-based micro-bumps or flip-chips (e.g., 130). In other embodiments, bond pads 758 may correspond to hybrid bond interconnects (e.g., high-density interconnects 126). In yet other embodiments, bond pads 758 may correspond to pads (e.g., 136) for DTPS interconnects. In some embodiments, the material of insulator 760 may be the same as the material of insulator 204. For example, insulator 760 may comprise a polyimide, and insulator 204 may also comprise the polyimide. In other embodiments, the material of insulator 760 may be different from the material of insulator 204. For example, insulator 760 may comprise silicon oxide and insulator 204 may comprise mold compound.

FIG. 7G shows microelectronic assembly 770 subsequent to attaching third-level IC die 110 over bonding layer 756. In various embodiments, third-level IC die 110 may be attached with DTD interconnects 130, for example, hybrid bond interconnects, micro-bumps or fine pitch flip-chips. In other embodiments, depending on the size and pitch of bond pads 758, third-level IC die 110 may be attached using high-density interconnects 126. In yet other embodiments, depending on the size and pitch of bond pads 758, third-level IC die 110 may be attached using DTPS interconnects. In some embodiments, bond pads 758 may be formed of solder; in other embodiments, bond pads 758 may be formed of some other conductive metal, such as copper.

FIG. 7H shows microelectronic assembly 780 subsequent to depositing insulator 208 over bonding layer 756 and around third-level IC die 110 and forming through-connections 122 (e.g., TMVs). In some embodiments, surface 782 of third level 116 may be polished, for example, by CMP.

FIG. 7I shows microelectronic assembly 100 subsequent to singulation from wafer form and separating from carrier wafer 752. In various embodiments, microelectronic assembly 100 may be handled like any other single/monolithic semiconductor die for further processing. For example, microelectronic assembly 100 may be assembled in a package with other microelectronic assemblies and/or dies to form a complete IC, such as a microprocessor.

FIG. 7J shows microelectronic assembly 100 attached to carrier wafer 702 and handled similar to second-level IC die 108 in FIGS. 7A-7C. For example, insulating material may be deposited around microelectronic assembly 100, additional microelectronic assemblies attached over the layer so formed, and so on. The processes described in FIGS. 7A-7I may be repeated any number of times as desired to make a stacked microelectronic assembly comprising any number of levels of dies and/or microelectronic assemblies.

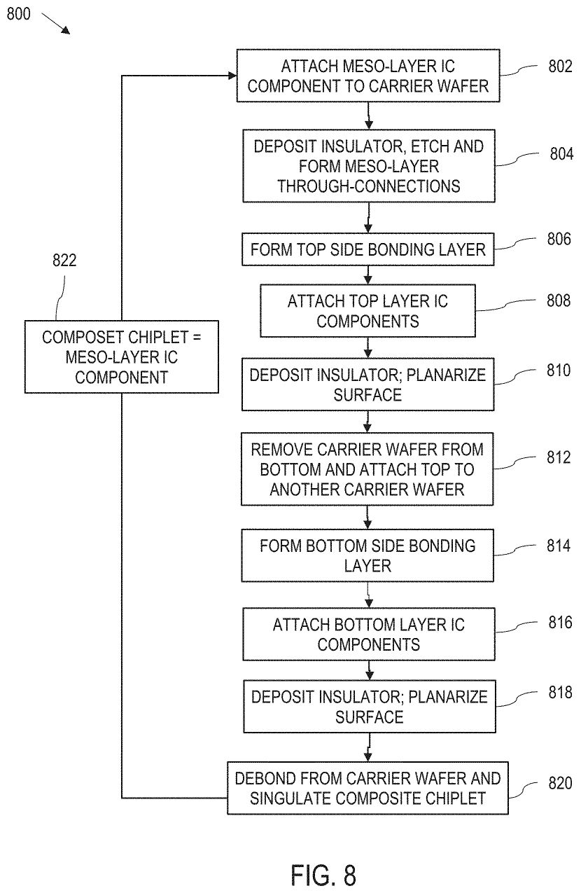

FIG. 8 is a flow diagram of an example method 800 of fabricating microelectronic assembly 100, according to various embodiments of the present disclosure. Although FIG. 8 illustrates various operations performed in a particular order, this is simply illustrative, and the operations discussed herein may be reordered and/or repeated as suitable. Further, additional processes which are not illustrated may also be performed without departing from the scope of the present disclosure. Also, various ones of the operations discussed herein with respect to FIG. 8 may be modified in accordance with the present disclosure to fabricate others of microelectronic assembly 100 disclosed herein.

At 802, second-level IC die 108 may be attached to carrier wafer (e.g., 702 as shown in FIG. 7A). At 804, an insulator (e.g., 204) may be deposited around the second-level IC die 108 and through-connections (e.g., 120) may be formed therein. At 806, a top side bonding layer (e.g., 722) may be formed. At 808, first-level IC die 106 may be attached to a top surface (e.g., 124) of the assembly. At 810, another insulator (e.g., 202) may be deposited on second level 114 and around first-level IC die 106, and its free surface planarized using a suitable process. At 812, the assembly may be removed from the carrier wafer (e.g., 702) and turned over, such that the top may be attached to another carrier wafer (e.g., 752). At 814, a bottom-side bonding layer (e.g., 756) may be formed. At 816, third-level IC die 110 may be attached, for example, by solder reflow. At 818, yet another insulator (e.g., 208) may be deposited on the surface of the assembly, TMVs 122 formed, and the surface planaraized. At 820, the assembly may be debonded from the carrier wafer and singulated into individual microelectronic assemblies 100. At 822, microelectronic assembly 100 may be handled as second-level IC die 108, and the operations may wrap around to 802 and continue thereafter until the desired microelectronic assembly is obtained.

Although the operations of method 800 are illustrated in FIG. 8 once each and in a particular order, the operations may be performed in any suitable order and repeated as desired. For example, one or more operations may be performed in parallel to manufacture multiple IC packages substantially simultaneously. In another example, the operations may be performed in a different order to reflect the structure of a particular IC package in which one or more microelectronic assembly 100 as described herein may be included. Numerous variations also possible to achieve the desired structure of microelectronic assembly 100.

Furthermore, the operations illustrated in FIG. 8 may be combined or may include more details than described. Still further, method 800 shown in FIG. 8 may further include other manufacturing operations related to fabrication of other components of the semiconductor assemblies described herein, or any devices that may include semiconductor assemblies as described herein. For example, method 800 may include various cleaning operations, surface planarization operations (e.g., using CMP), operations for surface roughening, operations to include barrier and/or adhesion layers as desired, and/or operations for incorporating packages as described herein in, or with, an IC die, a computing device, or any desired structure or device.

### Example Devices and Components

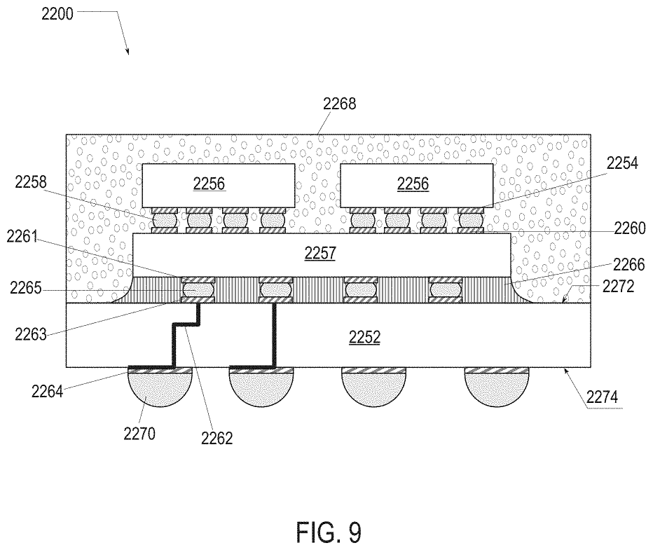

The packages disclosed herein, e.g., any of the embodiments shown in FIGS. 1-7 or any further embodiments described herein, may be included in any suitable electronic component. FIGS. 9-11 illustrate various examples of packages, assemblies, and devices that may be used with or include any of the IC packages as disclosed herein.

FIG. 9 is a side, cross-sectional view of an example IC package 2200 that may include IC packages in accordance with any of the embodiments disclosed herein. In some embodiments, the IC package 2200 may be a system-in-package (SiP).

As shown in the figure, package substrate 2252 may be formed of an insulator (e.g., a ceramic, a buildup film, an epoxy film having filler particles therein, etc.), and may have conductive pathways extending through the insulator between first face 2272 and second face 2274, or between different locations on first face 2272, and/or between different locations on second face 2274. These conductive pathways may take the form of any of the interconnect structures comprising lines and/or vias.

Package substrate 2252 may include conductive contacts 2263 that are coupled to conductive pathway 2262 through package substrate 2252, allowing circuitry within dies 2256 and/or interposer 2257 to electrically couple to various ones of conductive contacts 2264 (or to other devices included in package substrate 2252, not shown).

IC package 2200 may include interposer 2257 coupled to package substrate 2252 via conductive contacts 2261 of interposer 2257, first-level interconnects 2265, and conductive contacts 2263 of package substrate 2252. First-level interconnects 2265 illustrated in the figure are solder bumps, but any suitable first-level interconnects 2265 may be used, such as solder bumps, solder posts, or bond wires.

IC package 2200 may include one or more dies 2256 coupled to interposer 2257 via conductive contacts 2254 of dies 2256, first-level interconnects 2258, and conductive contacts 2260 of interposer 2257. Conductive contacts 2260 may be coupled to conductive pathways (not shown) through interposer 2257, allowing circuitry within dies 2256 to electrically couple to various ones of conductive contacts 2261 (or to other devices included in interposer 2257, not shown). First-level interconnects 2258 illustrated in the figure are solder bumps, but any suitable first-level interconnects 2258 may be used, such as solder bumps, solder posts, or bond wires. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

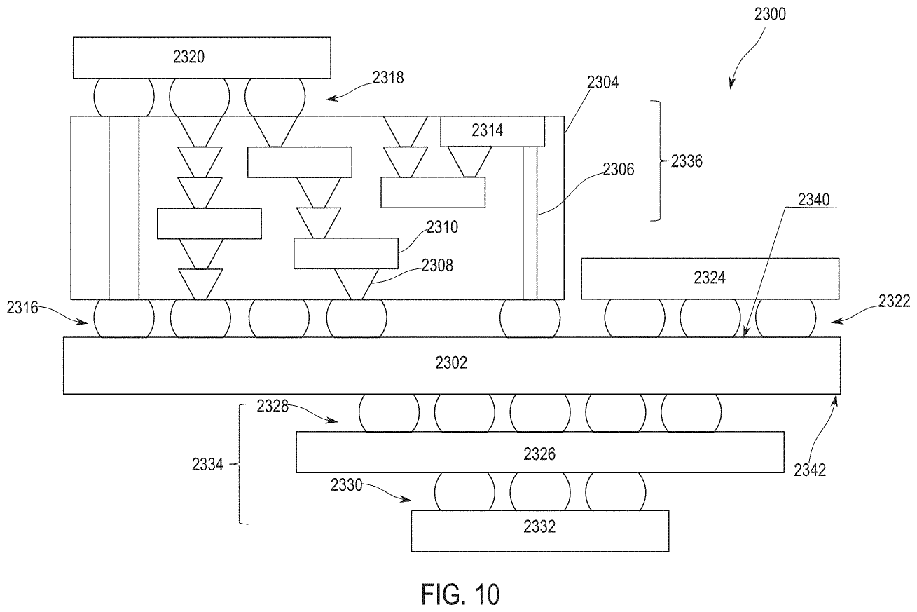

In some embodiments, underfill material 2266 may be disposed between package substrate 2252 and interposer 2257 around first-level interconnects 2265, and mold 2268 may be disposed around dies 2256 and interposer 2257 and in contact with package substrate 2252. In some embodiments, underfill material 2266 may be the same as mold 2268. Example materials that may be used for underfill material 2266 and mold 2268 are epoxies as suitable. Second-level interconnects 2270 may be coupled to conductive contacts 2264. Second-level interconnects 2270 illustrated in the figure are solder balls (e.g., for a ball grid array (BGA) arrangement), but any suitable second-level interconnects 2270 may be used (e.g., pins in a pin grid array arrangement or lands in a land grid array arrangement). Second-level interconnects 2270 may be used to couple IC package 2200 to another component, such as a circuit board (e.g., a motherboard), an interposer, or another IC package, as known in the art and as discussed below with reference to FIG. 10.

In various embodiments, any of dies 2256 may be microelectronic assembly 100 as described herein. In embodiments in which IC package 2200 includes multiple dies 2256, IC package 2200 may be referred to as a multi-chip package (MCP). Dies 2256 may include circuitry to perform any desired functionality. For example, besides one or more of dies 2256 being microelectronic assembly 100 as described herein, one or more of dies 2256 may be logic dies (e.g., silicon-based dies), one or more of dies 2256 may be memory dies (e.g., high-bandwidth memory), etc. In some embodiments, any of dies 2256 may be implemented as discussed with reference to any of the previous figures. In some embodiments, at least some of dies 2256 may not include implementations as described herein.

Although IC package 2200 illustrated in the figure is a flip-chip package, other package architectures may be used. For example, IC package 2200 may be a BGA package, such as an embedded wafer-level ball grid array (eWLB) package. In another example, IC package 2200 may be a wafer-level chip scale package (WLCSP) or a panel fan-out (FO) package. Although two dies 2256 are illustrated in IC package 2200, IC package 2200 may include any desired number of dies 2256. IC package 2200 may include additional passive components, such as surface-mount resistors, capacitors, and inductors disposed over first face 2272 or second face 2274 of package substrate 2252, or on either face of interposer 2257. More generally, IC package 2200 may include any other active or passive components known in the art.

In some embodiments, no interposer 2257 may be included in IC package 2200; instead, dies 2256 may be coupled directly to conductive contacts 2263 at first face 2272 by first-level interconnects 2265.

FIG. 10 is a cross-sectional side view of an IC device assembly 2300 that may include components having one or more microelectronic assembly 200 in accordance with any of the embodiments disclosed herein. IC device assembly 2300 includes a number of components disposed over a circuit board 2302 (which may be, e.g., a motherboard). IC device assembly 2300 includes components disposed over a first face 2340 of circuit board 2302 and an opposing second face 2342 of circuit board 2302; generally, components may be disposed over one or both faces 2340 and 2342. In particular, any suitable ones of the components of IC device assembly 2300 may include any of the one or more microelectronic assembly 200 in accordance with any of the embodiments disclosed herein; e.g., any of the IC packages discussed below with reference to IC device assembly 2300 may take the form of any of the embodiments of IC package 2200 discussed above with reference to FIG. 9.

In some embodiments, circuit board 2302 may be a PCB including multiple metal layers separated from one another by layers of insulator and interconnected by electrically conductive vias. Any one or more of the metal layers may be formed in a desired circuit pattern to route electrical signals (optionally in conjunction with other metal layers) between the components coupled to circuit board 2302. In other embodiments, circuit board 2302 may be a non-PCB package substrate.

As illustrated in the figure, in some embodiments, IC device assembly 2300 may include a package-on-interposer structure 2336 coupled to first face 2340 of circuit board 2302 by coupling components 2316. Coupling components 2316 may electrically and mechanically couple package-on-interposer structure 2336 to circuit board 2302, and may include solder balls (as shown), male and female portions of a socket, an adhesive, an underfill material, and/or any other suitable electrical and/or mechanical coupling structure.

Package-on-interposer structure 2336 may include IC package 2320 coupled to interposer 2304 by coupling components 2318. Coupling components 2318 may take any suitable form depending on desired functionalities, such as the forms discussed above with reference to coupling components 2316. In some embodiments, IC package 2320 may be or include IC package 2200, e.g., as described above with reference to FIG. 9. In some embodiments, IC package 2320 may include at least one microelectronic assembly 100 as described herein. Microelectronic assembly 100 is not specifically shown in the figure in order to not clutter the drawing.

Although a single IC package 2320 is shown in the figure, multiple IC packages may be coupled to interposer 2304; indeed, additional interposers may be coupled to interposer 2304. Interposer 2304 may provide an intervening package substrate used to bridge circuit board 2302 and IC package 2320. Generally, interposer 2304 may redistribute a connection to a wider pitch or reroute a connection to a different connection. For example, interposer 2304 may couple IC package 2320 to a BGA of coupling components 2316 for coupling to circuit board 2302.

In the embodiment illustrated in the figure, IC package 2320 and circuit board 2302 are attached to opposing sides of interposer 2304. In other embodiments, IC package 2320 and circuit board 2302 may be attached to a same side of interposer 2304. In some embodiments, three or more components may be interconnected by way of interposer 2304.

Interposer 2304 may be formed of an epoxy resin, a fiberglass-reinforced epoxy resin, a ceramic material, or a polymer material such as polyimide. In some implementations, interposer 2304 may be formed of alternate rigid or flexible materials that may include the same materials described above for use in a semiconductor substrate, such as silicon, germanium, and other group III-V and group IV materials. Interposer 2304 may include metal interconnects 2308 and vias 2310, including but not limited to TSVs 2306. Interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency (RF) devices, power amplifiers, power management devices, antennas, arrays, sensors, and microelectromechanical systems (MEMS) devices may also be formed on interposer 2304. Package-on-interposer structure 2336 may take the form of any of the package-on-interposer structures known in the art.

In some embodiments, IC device assembly 2300 may include an IC package 2324 coupled to first face 2340 of circuit board 2302 by coupling components 2322. Coupling components 2322 may take the form of any of the embodiments discussed above with reference to coupling components 2316, and IC package 2324 may take the form of any of the embodiments discussed above with reference to IC package 2320.

In some embodiments, IC device assembly 2300 may include a package-on-package structure 2334 coupled to second face 2342 of circuit board 2302 by coupling components 2328. Package-on-package structure 2334 may include an IC package 2326 and an IC package 2332 coupled together by coupling components 2330 such that IC package 2326 is disposed between circuit board 2302 and IC package 2332. Coupling components 2328 and 2330 may take the form of any of the embodiments of coupling components 2316 discussed above, and IC packages 2326 and/or 2332 may take the form of any of the embodiments of IC package 2320 discussed above. Package-on-package structure 2334 may be configured in accordance with any of the package-on-package structures known in the art.

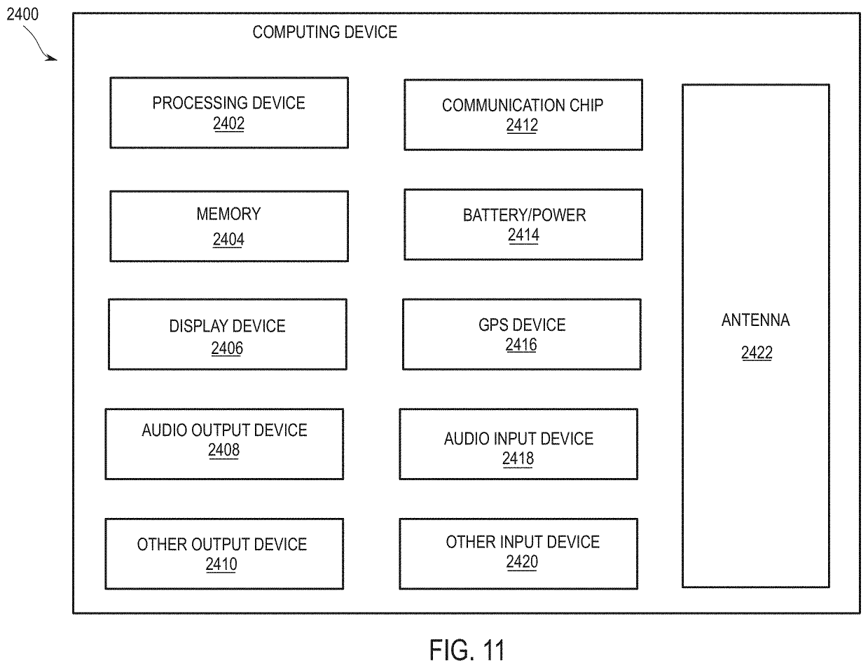

FIG. 11 is a block diagram of an example computing device 2400 that may include one or more components having one or more IC packages in accordance with any of the embodiments disclosed herein. For example, any suitable ones of the components of computing device 2400 may include a microelectronic assembly with a microelectronic assembly (e.g., 100), in accordance with any of the embodiments disclosed herein. In another example, any one or more of the components of computing device 2400 may include any embodiments of IC package 2200 (e.g., as shown in FIG. 9). In yet another example, any one or more of the components of computing device 2400 may include an IC device assembly 2300 (e.g., as shown in FIG. 10).

A number of components are illustrated in the figure as included in computing device 2400, but any one or more of these components may be omitted or duplicated, as suitable for the application. In some embodiments, some or all of the components included in computing device 2400 may be attached to one or more motherboards. In some embodiments, some or all of these components are fabricated onto a single SoC die.

Additionally, in various embodiments, computing device 2400 may not include one or more of the components illustrated in the figure, but computing device 2400 may include interface circuitry for coupling to the one or more components. For example, computing device 2400 may not include a display device 2406, but may include display device interface circuitry (e.g., a connector and driver circuitry) to which display device 2406 may be coupled. In another set of examples, computing device 2400 may not include an audio input device 2418 or an audio output device 2408, but may include audio input or output device interface circuitry (e.g., connectors and supporting circuitry) to which audio input device 2418 or audio output device 2408 may be coupled.

Computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. Processing device 2402 may include one or more digital signal processors (DSPs), ASICs, CPUs, GPUs, cryptoprocessors (specialized processors that execute cryptographic algorithms within hardware), server processors, or any other suitable processing devices. Computing device 2400 may include a memory 2404, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, memory 2404 may include memory that shares a die with processing device 2402. This memory may be used as cache memory and may include embedded dynamic random access memory (eDRAM) or spin transfer torque magnetic random access memory (STT-MRAM).

In some embodiments, computing device 2400 may include a communication chip 2412 (e.g., one or more communication chips). For example, communication chip 2412 may be configured for managing wireless communications for the transfer of data to and from computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 2412 may operate in accordance with other wireless protocols in other embodiments. Computing device 2400 may include an antenna 2422 to facilitate wireless communications and/or to receive other wireless communications (such as AM or FM radio transmissions).

In some embodiments, communication chip 2412 may manage wired communications, such as electrical, optical, or any other suitable communication protocols (e.g., the Ethernet). As noted above, communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

Computing device 2400 may include battery/power circuitry 2414. Battery/power circuitry 2414 may include one or more energy storage devices (e.g., batteries or capacitors) and/or circuitry for coupling components of computing device 2400 to an energy source separate from computing device 2400 (e.g., AC line power).

Computing device 2400 may include a display device 2406 (or corresponding interface circuitry, as discussed above). Display device 2406 may include any visual indicators, such as a heads-up display, a computer monitor, a projector, a touchscreen display, a liquid crystal display (LCD), a light-emitting diode display, or a flat panel display, for example.

Computing device 2400 may include audio output device 2408 (or corresponding interface circuitry, as discussed above). Audio output device 2408 may include any device that generates an audible indicator, such as speakers, headsets, or earbuds, for example.

Computing device 2400 may include audio input device 2418 (or corresponding interface circuitry, as discussed above). Audio input device 2418 may include any device that generates a signal representative of a sound, such as microphones, microphone arrays, or digital instruments (e.g., instruments having a musical instrument digital interface (MIDI) output).

Computing device 2400 may include a GPS device 2416 (or corresponding interface circuitry, as discussed above). GPS device 2416 may be in communication with a satellite-based system and may receive a location of computing device 2400, as known in the art.

Computing device 2400 may include other output device 2410 (or corresponding interface circuitry, as discussed above). Examples of other output device 2410 may include an audio codec, a video codec, a printer, a wired or wireless transmitter for providing information to other devices, or an additional storage device.

Computing device 2400 may include other input device 2420 (or corresponding interface circuitry, as discussed above). Examples of other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, computing device 2400 may be any other electronic device that processes data.

### Select Examples

The following paragraphs provide various examples of the embodiments disclosed herein.

Example 1 provides a microelectronic assembly (e.g., 100), comprising: a first IC die (e.g., 106) at a first level (e.g., 112); a second IC die (e.g., 108) at a second level (e.g., 114); and a third IC die (e.g., 110) at a third level (e.g., 116). The second level is in between the first level and the third level. A first interface (e.g., 124) between the first level and the second level is electrically coupled with first interconnects (e.g., 126) having a first pitch (e.g., 206), and a second interface (e.g., 128) between the second level and the third level is electrically coupled with second interconnects (e.g., 130) having a second pitch (e.g., 210).

Example 2 provides the microelectronic assembly of example 1, in which at least one of the first IC die and the third IC die comprises a semiconductor interconnect bridge die having no active circuitry.

Example 3 provides the microelectronic assembly of any of examples 1-2, in which at least one of the first IC die and the third IC die comprises a semiconductor die having active circuitry.

Example 4 provides the microelectronic assembly of any of examples 1-3, in which at least one of the first IC die, the second IC die and the third IC die comprises another microelectronic assembly.

Example 5 provides the microelectronic assembly of any of examples 1-3, in which the second IC die comprises a semiconductor die with active circuitry in a semiconductor substrate and a metallization stack over the active circuitry.

Example 6 provides the microelectronic assembly of any of examples 1-5, in which the interconnects of the second pitch comprise hybrid bond interconnects, micro-bumps or flip-chip interconnects and the second pitch is larger than the first pitch.

Example 7 provides the microelectronic assembly of any of examples 1-6, in which the microelectronic assembly is a PE (e.g., 104) of a larger IC (e.g., FIGS. 1A, 4A-4C).

Example 8 provides the microelectronic assembly of example 7, in which the first IC die comprises an electrical interconnect circuit block (e.g., 102(4)) coupling two different circuit blocks (e.g., 102(1) and 102(2)) in the PE, and the third IC die comprises an electrical interconnect circuit block (e.g., 102(5)) coupling the PE with another PE in the larger IC.

Example 9 provides the microelectronic assembly of any of examples 1-8, further comprising: through-connections (e.g., 120) in the second level; and through-connections (e.g., 122) in the third level. The through-connections in the second level are at a smaller pitch than the through-connections in the third level.

Example 10 provides the microelectronic assembly of example 9, in which the first IC die in the first level is electrically coupled to the third IC die in the third level with the through-connections in the second level (e.g., FIG. 2).

Example 11 provides the microelectronic assembly of any of examples 9-10, in which the through-connections in the second level and the third level supply power to the first level.

Example 12 provides the microelectronic assembly of any of examples 9-11, in which the first IC die and the third IC die comprise semiconductor dies having TSVs (e.g., 132, 134).

Example 13 provides the microelectronic assembly of any of examples 9-12, in which the TSVs (e.g., 132) in the first IC die are at a smaller pitch than the TSVs (e.g., 134) in the third IC die.

Example 14 provides the microelectronic assembly of any of examples 1-13, in which the first IC die and the second IC die are connected face-to-face with hybrid bond interconnects (e.g., 126).

Example 15 provides the microelectronic assembly of any of examples 1-14, in which: the first IC die is embedded in a first insulator (e.g., 202) in the first level; the second IC die is embedded in a second insulator (e.g., 204) in the second level; and the third IC die is embedded in a third insulator (e.g., 208) in the third level.

Example 16 provides the microelectronic assembly of example 15, in which the first insulator, the second insulator and the third insulator comprise different materials.

Example 17 provides the microelectronic assembly of example 15, in which the first insulator, the second insulator and the third insulator comprise the same material.

Example 18 provides the microelectronic assembly of example 15 or 17, in which the first insulator, the second insulator and the third insulator comprise silica filled epoxy.

Example 19 provides the microelectronic assembly of example 15 or 17, in which the first insulator, the second insulator and the third insulator comprise silicon oxide.

Example 20 provides the microelectronic assembly of any of examples 1-19, further comprising a redistribution layer proximate to the third level opposite to the second level.

Example 21 provides a microelectronic assembly, comprising: a microelectronic assembly (e.g., 100) having at least three levels with an IC die in each level; and a package substrate coupled to the microelectronic assembly. A first interface (e.g., 124) between a first level (e.g., 112) and a second level (e.g., 114) in the at least three levels of the microelectronic assembly comprises interconnects of a first pitch, a second interface (128) between the second level and a third level (116) in the at least three levels of the microelectronic assembly comprises interconnects of a second pitch, and a third interface between the microelectronic assembly and the package substrate comprises interconnects (214) of a third pitch.

Example 22 provides the microelectronic assembly of example 21, in which the first pitch is smaller than the second pitch.

Example 23 provides the microelectronic assembly of any of examples 21-22, in which the second pitch is smaller than the third pitch.

Example 24 provides the microelectronic assembly of any of examples 21-23, in which the package substrate comprises an organic interposer (502) with an embedded semiconductor die (506).

Example 25 provides the microelectronic assembly of any of examples 21-23, in which the package substrate comprises a PCB.

Example 26 provides the microelectronic assembly of any of examples 21-23, in which the package substrate comprises a semiconductor die (602).

Example 27 provides the microelectronic assembly of any of examples 21-26, in which at least one IC die in the microelectronic assembly is another microelectronic assembly.

Example 28 provides the microelectronic assembly of any of examples 21-27, in which at least one IC die in the microelectronic assembly is a passive semiconductor die without active circuitry.

Example 29 provides the microelectronic assembly of any of examples 21-28, in which at least one IC die in the microelectronic assembly is a plurality of semiconductor dies stacked one on top of another.

Example 30 provides the microelectronic assembly of any of examples 21-29, further comprising a plurality of microelectronic assemblies coupled to the package substrate (e.g., FIGS. 4A-4C).

Example 31 provides a method comprising: coupling a plurality of IC dies into three levels to form a microelectronic assembly. A first interface between a first level and a second level comprises interconnects of a first pitch, a second interface between the second level and a third level comprises interconnects of a second pitch, and the plurality of IC dies are electrically coupled such that the microelectronic assembly forms a portion of a PE.

Example 32 provides the method of example 31, in which the coupling comprises forming the second level, including: providing a carrier wafer; attaching an IC die on the carrier wafer; depositing an insulator on the carrier wafer around the IC die; and forming through-connections in the insulator.

Example 33 provides the method of example 32, further comprising forming the first level, including: forming a bonding layer comprising bond pads in insulator; coupling another IC die to the bond pads; depositing another insulator over the bonding layer around the another IC die; and polishing a surface of the first level to form a polished surface.

Example 34 provides the method of examples 33, in which the bond pads are sized for high-density interconnects.

Example 35 provides the method of any of examples 33-34, further comprising forming the third level, including: separating the carrier wafer; coupling another carrier wafer to the polished surface of the first level; forming another bonding layer comprising bond pads in insulator; coupling yet another IC die to the bond pads of the another bonding layer; depositing yet another insulator over the another bonding layer around the yet another IC die; and forming through-connections in the yet another insulator.

Example 36 provides the method of example 35, in which the bonds of the another bonding layer are sized for at least one of hybrid bond interconnects, micro-bumps and flip-chip interconnects.

Example 37 provides the method of any of examples 35-36, further comprising separating the another carrier wafer and singulating to form the microelectronic assembly.

Example 38 provides the method of any of examples 35-37, in which the through-connections in the third level have a larger pitch than the through-connections in the second level.

Example 39 provides the method of any of examples 31-38, in which at least one of the IC dies comprises a microelectronic assembly.

Example 40 provides the method of any of examples 31-39, in which at least one of the IC dies comprises a semiconductor die.

The above description of illustrated implementations of the disclosure, including what is described in the abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

1. A microelectronic assembly, comprising:
a first integrated circuit (IC) die at a first level;
a second IC die at a second level; and
a third IC die at a third level, wherein:
the second level is between the first level and the third level,
a first interface between the first level and the second level is electrically coupled with first interconnects having a first pitch,
a second interface between the second level and the third level is electrically coupled with second interconnects having a second pitch, and
the second pitch is larger than the first pitch.

2. The microelectronic assembly of claim 1, wherein at least one of the second IC die and the third IC die comprises a semiconductor interconnect bridge die having no active circuitry.

3. The microelectronic assembly of claim 1, wherein at least one of the first IC die, the second IC die and the third IC die comprises another microelectronic assembly.

4. The microelectronic assembly of claim 1, wherein the first interconnects comprise hybrid bond interconnects.

5. The microelectronic assembly of claim 1, wherein the microelectronic assembly is a processing element (PE) of a larger IC.

6. The microelectronic assembly of claim 5, wherein the second IC die comprises an electrical interconnect circuit block coupling two different circuit blocks in the PE, and the third IC die comprises an electrical interconnect circuit block coupling the PE with another PE in the larger IC.

7. The microelectronic assembly of claim 1, further comprising:
through-connections in the second level; and
through-connections in the third level, wherein the through-connections in the second level are at a smaller pitch than the through-connections in the third level.

8. The microelectronic assembly of claim 1, wherein:
the first IC die is embedded in a first insulator in the first level;
the second IC die is embedded in a second insulator in the second level; and
the third IC die is embedded in a third insulator in the third level.

9. The microelectronic assembly of claim 8, wherein the first insulator, the second insulator and the third insulator comprise the same material.

10. A microelectronic assembly, comprising:
a microelectronic assembly having at least three levels with an IC die in each level; and
a package substrate coupled to the microelectronic assembly, wherein:
a first interface between a first level and a second level in the at least three levels of the microelectronic assembly comprises interconnects of a first pitch,
a second interface between the second level and a third level in the at least three levels of the microelectronic assembly comprises interconnects of a second pitch, and
a third interface between the microelectronic assembly and the package substrate comprises interconnects of a third pitch.

11. The microelectronic assembly of claim 10, wherein the first pitch is smaller than the second pitch.

12. The microelectronic assembly of claim 11, wherein the second pitch is smaller than the third pitch.

13. The microelectronic assembly of claim 10, wherein the package substrate comprises an organic interposer with an embedded semiconductor die.

14. The microelectronic assembly of claim 10, wherein the package substrate comprises a printed circuit board (PCB).

15. The microelectronic assembly of claim 10, wherein at least one IC die in the microelectronic assembly comprises another microelectronic assembly.

16. The microelectronic assembly of claim 10, wherein at least one IC die in the microelectronic assembly comprises a passive semiconductor die without active circuitry.

17. A method comprising:
coupling a plurality of IC dies into three levels to form a microelectronic assembly, wherein:
a first interface between a first level and a second level comprises high-density interconnects of a first pitch,
a second interface between the second level and a third level comprises interconnects of a second pitch, and
the plurality of IC dies is electrically coupled such that the microelectronic assembly forms a portion of a PE.

18. The method of claim 17, wherein the coupling comprises forming the second level, including:
providing a carrier wafer;
attaching an IC die on the carrier wafer;
depositing an insulator on the carrier wafer around the IC die; and
forming through-connections in the insulator.

19. The method of claim 18, further comprising forming the first level, including:
forming a bonding layer comprising bond pads in insulator;
coupling another IC die to the bond pads;
depositing another insulator over the bonding layer around the another IC die; and
polishing a surface of the first level to form a polished surface.

20. The method of claim 19, further comprising forming the third level, including:
separating the carrier wafer;
coupling another carrier wafer to the polished surface of the first level;
forming another bonding layer comprising bond pads in insulator;
coupling yet another IC die to the bond pads of the another bonding layer;
depositing yet another insulator over the another bonding layer around the yet another IC die; and
forming through-connections in the yet another insulator.
